(19) United States
(12) Patent Application Publication
(10) Pub. No.: US 2026/0130193 A1
(43) Pub. Date: May 7, 2026

(54) SEMICONDUCTOR CHIP AND SEMICONDUCTOR PACKAGE INCLUDING THE SAME

(71) Applicant: SAMSUNG ELECTRONICS CO., LTD., Suwon-si (KR)

(72) Inventor: Hyunsoo CHUNG, Suwon-si (KR)

(73) Assignee: SAMSUNG ELECTRONICS CO., LTD., Suwon-si (KR)

(21) Appl. No.: 19/350,787

(22) Filed: Oct. 6, 2025

(30) Foreign Application Priority Data
Nov. 6, 2024 (KR) 10-2024-0156279

(51) Int. Cl. H01L 23/48; H01L 23/00; H01L 25/07

(52) U.S. Cl. CPC H10W 20/20; H10W 90/00; H10W 70/65; H10W 72/944

(57) ABSTRACT

A semiconductor chip and a semiconductor package are disclosed. The semiconductor chip includes a device layer having a semiconductor device disposed on a front side of a substrate, and a first through via extending in a first direction intersecting the front side of the substrate and penetrating the substrate and at least a portion of the device layer. The first through via includes a first front side part that penetrates the front side of the substrate and at least a portion of the device layer, and a first back side part that is located in the substrate, connected to the first front side part, and positioned closer to a back side of the substrate than the first front side part. A width of the first back side part is greater than a width of the first front side part, thereby alleviating electrical resistance.

### CROSS-REFERENCE TO RELATED APPLICATION

This application claims the benefit of Korean Patent Application No. 10-2024-0156279, filed on Nov. 6, 2024, in the Korean Intellectual Property Office, the disclosure of which is incorporated herein by reference in its entirety.

### BACKGROUND

### 1. Field of the Invention

Example embodiments relate to a semiconductor chip and a semiconductor package including the same.

### 2. Description of the Related Art

Due to the development of the electronics industry, the demand for high-performance, high-speed, and miniaturized electronic components is increasing. In response to this trend, a method of stacking and mounting multiple semiconductor chips on a single package wiring structure and/or a method of stacking packages on top of packages can be used. For example, a package-in-package (PIP) type semiconductor package or a package-on-package (POP) type semiconductor package can be used.

Meanwhile, when a through silicon via (TSV) is used to penetrate a semiconductor chip, due to the high integration of semiconductor chips, there are limits in forming TSVs.

### SUMMARY

An aspect provides a semiconductor chip and a semiconductor package in which the electrical resistance is reduced.

An aspect provides a semiconductor chip and a semiconductor package in which manufacturing processes are improved.

The technical tasks to be achieved by the present example embodiments are not limited to the technical tasks described above, and other technical tasks may be inferred from the following example embodiments by those skilled in the art.

According to an aspect, there is provided a semiconductor chip including a device layer including a semiconductor device placed on a front side of a substrate and a first through via extending in a first direction intersecting the front side of the substrate and penetrating the substrate and at least a portion of the device layer, wherein the first through via includes a first front side part penetrating the front side of the substrate and penetrating at least a portion of the device layer, and a first back side part that is placed in the substrate, connected to the first front side part and placed closer to a back side of the substrate than the first front side part, wherein the first back side part include a width that is greater than a width of the first front side part.

According to an aspect, there is provided a semiconductor chip including a device layer including a semiconductor device placed on a front side of a substrate, a first through via extending in a first direction intersecting the front side of the substrate and penetrating the substrate and at least a portion of the device layer, and a second through via that is spaced apart from the first through via in a second direction intersecting the first direction, and penetrating the substrate and at least a portion of the device layer, wherein the first through via includes a first front side part penetrating the front side of the substrate and penetrating at least a portion of the device layer, and a first back side part that is placed in the substrate, connected to the first front side part and placed closer to a back side of the substrate than the first front side part, and the second through via includes a second front side part penetrating the front side of the substrate and penetrating at least a portion of the device layer, and a second back side part that is placed in the substrate, connected to the second front side part, and placed closer to the back side of the substrate than the second front side part, wherein the first side part includes a width that is greater than a width of the second back side part.

According to an aspect, there is provided a semiconductor package including a package die and a plurality of semiconductor chips that are stacked in a first direction intersecting the package die, wherein each of the plurality of semiconductor chips includes a device layer including a semiconductor device placed on a front side of a substrate, a first through via extending in a first direction and penetrating the substrate and at least a portion of the device layer, and a second through via that is spaced apart from the first through via in a second direction intersecting the first direction, and penetrating the substrate and at least a portion of the device layer, wherein the first through via includes a first front side part penetrating the front side of the substrate and penetrating at least a portion of the device layer and a first back side part that is placed in the substrate, connected to the first front side part and placed closer to a back side of the substrate than the first front side part, and the second through via includes a second front side part penetrating the front side of the substrate and penetrating at least a portion of the device layer, a second back side part that is placed in the substrate, connected to the second front side part, and placed closer to the back side of the substrate than the second front side part, wherein a maximum width of the first back side part is greater than a maximum width of the second back side part, wherein a plurality of the first through via of the plurality of semiconductor chips overlap each other in the first direction, and wherein a plurality of the second through via of the plurality of semiconductor chips overlap each other in the first direction.

Additional aspects of example embodiments will be set forth in part in the description which follows and, in part, will be apparent from the description, or may be learned by practice of the disclosure.

### BRIEF DESCRIPTION OF THE FIGURES

These and/or other aspects, features, and advantages of the invention will become apparent and more readily appreciated from the following description of example embodiments, taken in conjunction with the accompanying drawings of which:

FIG. 1 is a schematic drawing illustrating a semiconductor chip according to an example embodiment;

FIG. 2 is a drawing illustrating an enlarged view of a portion R of FIG. 1;

FIG. 3 is a drawing illustrating an enlarged view of the portion R of FIG. 1 to explain a semiconductor chip according to an example embodiment;

FIG. 4 is a drawing illustrating an enlarged view of the portion R of FIG. 1 to explain a semiconductor chip according to an example embodiment;

FIG. 5 is a drawing illustrating an enlarged view of the portion R of FIG. 1 to explain a semiconductor chip according to an example embodiment;

FIG. 6 is a drawing illustrating an enlarged view of the portion R of FIG. 1 to explain a semiconductor chip according to an example embodiment;

FIG. 7 is a drawing illustrating an enlarged view of the portion R of FIG. 1 to explain a semiconductor chip according to an example embodiment;

FIG. 8 is a schematic drawing illustrating a semiconductor package according to an example embodiment; and

FIG. 9 to FIG. 16 are schematic drawings illustrating intermediate operations for explaining a method of manufacturing a semiconductor chip according to the example embodiment illustrated in FIG. 1.

### DETAILED DESCRIPTION

Prior to the detailed description of the present disclosure, terms or words used in the specification and claims should not be construed as limited to their common or dictionary meanings. Further, the terms or words should be interpreted with meaning and concept consistent with the technical idea of the present disclosure based on the principle that the inventor may appropriately define the concept of terms in order to explain his or her invention in the best way. The example embodiments described in this specification and the configurations shown in the drawings are merely preferred embodiments of the present disclosure, and do not necessarily represent the entire technical idea of the present disclosure. Accordingly, at the time of filing the present disclosure, there may be various equivalents and modifications that can replace them.

In the following description, singular expressions include plural expressions unless the context clearly dictates otherwise. It will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. The terms “have,” “may have,” “include,” and “may include” as used herein indicate the presence of corresponding features (for example, elements such as numerical values, functions, operations, or parts), and do not preclude the presence of additional features.

In the present disclosure, singular expressions include plural expressions unless the context clearly indicates otherwise. Further, terms “first,” “second” and so on may be used to describe various components. However, the components are not limited by the terms, and the terms may be used for the purpose of distinguishing one component from another. Within the scope of the technical idea of the present disclosure, the first component may be named as the second component. Similarly, the second component may also be named the first component. Further, the shape and size of components may be exaggerated to emphasize clear explanation.

Further, in the following description, expressions such as an upper side, top, a lower side, bottom, a side, front and a back side are expressed based on the direction shown in the drawing. If the direction of the object changes, it may be expressed differently. The shapes and sizes of elements in the drawings may be exaggerated for clearer explanation.

Hereinafter, example embodiments according to the technical idea of the present disclosure will be described with reference to the attached drawings.

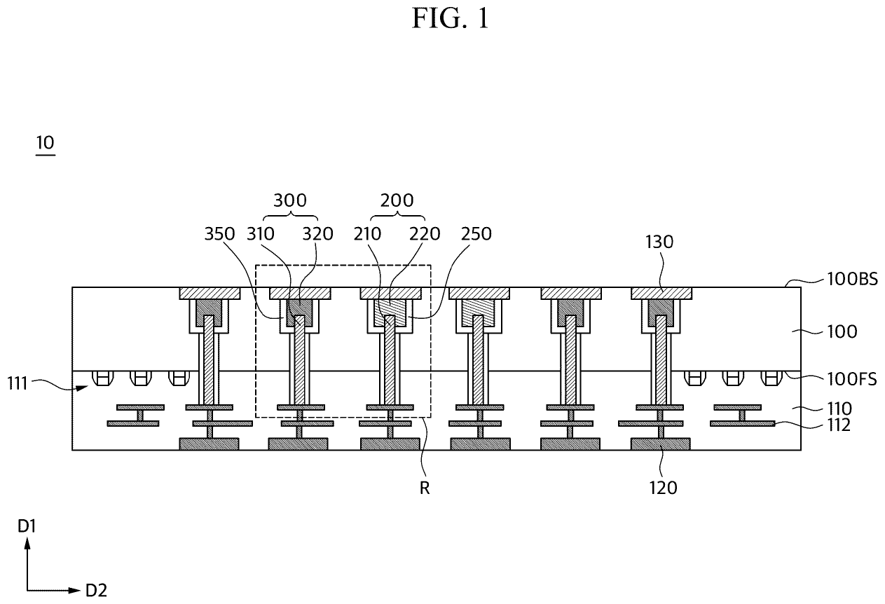

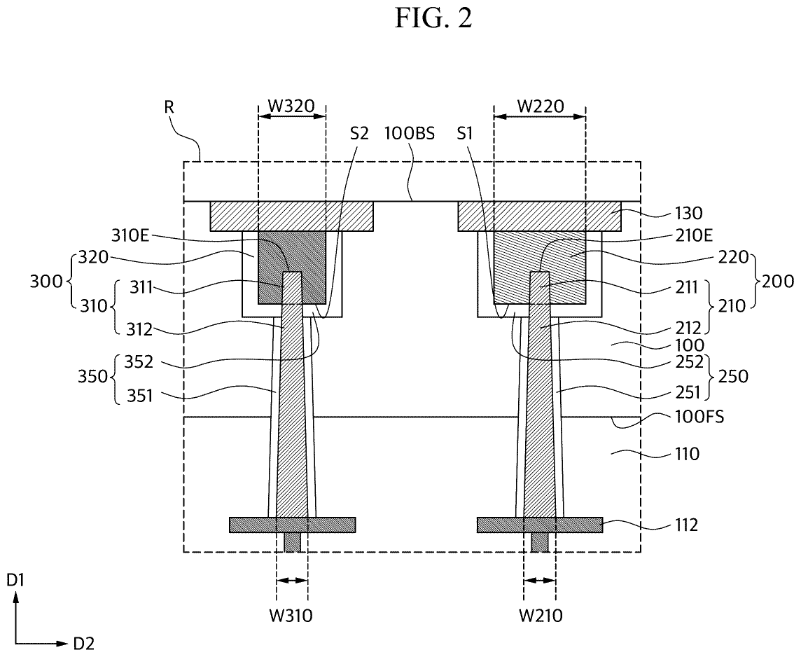

FIG. 1 is a schematic drawing illustrating a semiconductor chip according to an example embodiment. FIG. 2 is a drawing illustrating an enlarged view of the portion R of FIG. 1.

Referring to FIG. 1 and FIG. 2, according to some example embodiments, a semiconductor chip 10 may include a substrate 100, a device layer 110, a first through via 200 and a second through via 300.

According to some example embodiments, the semiconductor chip 10 may be an integrated circuit (IC) in which hundreds to millions of semiconductor devices are integrated into a single chip. For example, the semiconductor chip 10 may be a volatile memory chip such as dynamic random access memory (DRAM) and static random access memory (SRAM). Alternatively, the semiconductor chip 10 may be a non-volatile memory chip such as flash memory, phase-change RAM (PRAM), magnetoresistive RAM (MRAM), ferroelectric RAM (FeRAM), or resistive RAM (RRAM). In another example embodiment, the semiconductor chip 10 may include a logic chip. The semiconductor chip 10 may be an AP such as a Central Processing Unit (CPU), Graphic Processing Unit (GPU), Field-Programmable Gate Array (FPGA), digital signal processor, cryptographic processor, microprocessor and microcontroller. However, the semiconductor chip 10 is not limited thereto.

According to some example embodiments, the substrate 100 may be bulk silicon or silicon-on-insulator (SOI). In another example embodiment, the substrate 100 may be a silicon substrate. In another example embodiment, the substrate 100 may include silicon germanium, silicon germanium on insulator (SGOI), indium antimonide, lead telluride, indium arsenide, indium phosphide, gallium arsenide, or gallium antimonide. However, the semiconductor chip 10 is not limited thereto.

According to some example embodiments, the substrate 100 may include a conductive region, for example, a doped well or a doped structure. The substrate 100 may have various device isolation structures, such as a shallow trench isolation (STI) structure.

According to some example embodiments, the substrate 100 may have a front side 100FS and a back side 100BS. The front side 100FS of the substrate 100 may be a surface facing the device layer 110. The back side 100BS of the substrate 100 may be a surface that is positioned opposite to the front side 100FS of the substrate 100.

According to some example embodiments, the device layer 110 may be placed on a lower portion of the substrate 100. The device layer 110 may include a plurality of semiconductor devices 111 and interlayer insulation films. The plurality of semiconductor devices 111 may include various microelectronic devices. For example, included may be metal-oxide-semiconductor field effect transistors (MOSFETs) such as complementary metal-insulator-semiconductor (CMOS) transistors, system large scale integration (LSI), flash memory, DRAM, SRAM, EEPROM, PRAM, MRAM, RRAM, image sensors such as CMOS imaging sensor (CIS), micro-electro-mechanical system (MEMS), active elements, passive elements and so on.

According to some example embodiments, the plurality of semiconductor devices 111 of the device layer 110 may be electrically connected to a conductive region formed within the substrate 100. The plurality of semiconductor devices 111 of the device layer 110 may be electrically isolated from other neighboring plurality of semiconductor devices 111 by insulation films. The device layer 110 may include at least two of the plurality of semiconductor devices 111, or a wiring layer 112 electrically connecting the plurality of semiconductor devices 111 to a conductive region of the substrate 100.

According to some example embodiments, an insulating layer may be formed on the device layer 110 to protect the wiring layer 112 and other structures within the device layer 110 from external impact or moisture. The insulating layer may expose one side of a front side connecting pad 120.

According to some example embodiments, the wiring layer 112 may include a metal wiring layer and a via plug. For example, the wiring layer 112 may be a multilayer structure in which two or more metal wiring layers or two or more via plugs are alternately stacked. The wiring layer 112 may include conductive material. For example, the wiring layer 112 may include copper (Cu), aluminum (Al), silver (Ag), tin (Sn), gold (Au), nickel (Ni), lead (Pb), titanium (Ti), or alloys thereof. However, the wiring layer 112 is not limited thereto.

According to some example embodiments, the front side connecting pad 120 may be placed within the device layer 110. The front side connecting pad 120 may be electrically connected to the wiring layer 112 within the device layer 110. The front side connecting pad 120 may be electrically connected to the first through via 200 and the second through via 300 through the wiring layer 112. The front side connecting pad 120 may include at least one selected from aluminum (Al), copper (Cu), nickel (Ni), tungsten (W), platinum (Pt) and gold (Au), but the front side connecting pad 120 is not limited thereto. Even though FIG. 1 illustrates that the front side connecting pad 120 is placed within the device layer 110, example embodiments are not limited thereto. For example, a lower passivation layer may be placed to cover the lower surface of the device layer 110 and surround a portion of the side surface of the front side connecting pad 120. The lower passivation layer may expose a portion of the lower surface of the front side connecting pad 120.

According to some example embodiments, a back side connecting pad 130 may be placed within the substrate 100. The back side connecting pad 130 may be composed of the same material as the front side connecting pad 120. Even though FIG. 1 illustrates that the back side connecting pad 130 is placed within the substrate 100, example embodiments are not limited thereto. For example, an upper passivation layer may be formed on the upper surface of the substrate 100 to surround a portion of a side surface of the back side connecting pad 130. The upper passivation layer may expose a portion of the upper surface of the back side connecting pad 130.

According to some example embodiments, the first through via 200 and the second through via 300 may penetrate the substrate 100 and the device layer 110. The first through via 200 and the second through via 300 may penetrate at least a portion of the substrate 100 and at least a portion of the device layer 110, respectively. The first through via 200 and the second through via 300 may extend within the substrate 100 and the device layer 110 in the first direction D1. The first direction D1 may be a direction intersecting the front side 100FS of the substrate 100. The first through via 200 and the second through via 300 may be connected to the wiring layer 112 provided in the device layer 110.

According to some example embodiments, a plurality of first through vias 200 and a plurality of second through vias 300 may be placed spaced apart in the second direction D2. The second direction D2 may be a direction intersecting the first direction D1. For example, the second direction D2 may refer to a direction parallel to the front side 100FS of the substrate 100 or the back side 100BS of the substrate 100. The plurality of first through vias 200 may be placed spaced apart from each other in the second direction D2. The plurality of second through vias 300 may be placed spaced apart from each other in the second direction D2. The first through vias 200 and the second through vias 300 may be placed spaced apart from each other in the second direction D2.

According to some example embodiments, the first through via 200 may include a first front side part 210 and a first back side part 220. The first front side part 210 and the first back side part 220 may be placed in the first direction D1 and connected to each other. Each of the first front side part 210 and the first back side part 220 may include a conductive material. For example, the first front side part 210 and the first back side part 220 may include copper (Cu), aluminum (Al), silver (Ag), tin (Sn), gold (Au), nickel (Ni), lead (Pb), titanium (Ti), or alloys thereof. However, the first front side part 210 and the first back side part 220 are not limited thereto.

According to some example embodiments, the first front side part 210 may penetrate the front side 100FS of the substrate 100. The first front side part 210 may be connected to the wiring layer 112. The first front side part 210 may be placed adjacent to the device layer 110 compared to the first back side part 220. The first front side part 210 may extend in the first direction D1 over at least a portion of the substrate 100 and at least a portion of the device layer 110. The first front side part 210 may be at least partially inserted into the first back side part 220.

According to some example embodiments, the width of the first front side part 210 may be reduced as the first front side part 210 approaches the first back side part 220. The width of the first front side part 210 may refer to the width or diameter of the first front side part 210 along the second direction D2 intersecting the first direction D1. The width W210 of the first front side part 210 along the second direction D2 may be the same as the width W310 of a second front side part 310.

According to some example embodiments, the first front side part 210 may include a first connection part 211 and a first extension part 212. The first connection part 211 and the first extension part 212 may be placed in the first direction D1.

According to some example embodiments, the first connection part 211 may be inserted into the first back side part 220. The first connection part 211 may be surrounded by the first back side part 220. The first connection part 211 may be overlapped with the first back side part 220 and the second direction D2. The first connection part 211 may be connected to the first extension part 212 and first direction D1.

According to some example embodiments, the first extension part 212 may extend in the first direction D1 across the substrate 100 and the device layer 110. The first extension part 212 may be connected to the wiring layer 112. The first extension part 212 may electrically connect the wiring layer 112 and the first connection part 211. The first extension part 212 may penetrate at least a portion of the substrate 100 and at least a portion of the device layer 110. The first extension part 212 may not overlap the first back side part 220 in the second direction D2. The first extension part 212 may be connected to the first connection part 211 in the first direction D1.

According to some example embodiments, the first back side part 220 may be positioned closer to the back side 100BS of the substrate 100 than the first front side part 210. The first back side part 220 may be placed within the substrate 100. The first back side part 220 may be connected to the first front side part 210 in the first direction D1. The first back side part 220 may surround at least a portion of the first front side part 210. The first back side part 220 may surround the first connection part 211 of the first front side part 210. According to some example embodiments, the first back side part 220 may have a constant width in the second direction D2.

According to some example embodiments, the width of the first back side part 220 may be greater than the width of the first front side part 210. For example, the maximum width W220 of the first back side part 220 may be greater than the maximum width W210 of the first front side part 210. The width of the first back side part 220 along the second direction D2 may be constant.

According to some example embodiments, the second through via 300 may include the second front side part 310 and a second back side part 320. The second front side part 310 and the second back side part 320 may be placed in the first direction D1 and connected to each other. The second front side part 310 and the second back side part 320 may each include a conductive material. For example, the second front side part 310 and the second back side part 320 may include copper (Cu), aluminum (Al), silver (Ag), tin (Sn), gold (Au), nickel (Ni), lead (Pb), titanium (Ti), or alloys thereof. However, the second front side part 310 and the second back side part 320 are not limited thereto.

According to some example embodiments, the second front side part 310 may penetrate the front side 100FS of the substrate 100. The second front side part 310 may be connected to the wiring layer 112. The second front side part 310 may be placed adjacent to the device layer 110 compared to the second back side part 320. The second front side part 310 may extend in the first direction D1 over at least a portion of the substrate 100 and at least a portion of the device layer 110. The second front side part 310 may be at least partially inserted into the second back side part 320.

According to some example embodiments, the width of the second front side part 310 may be reduced as the second front side part 310 approaches the second back side part 320. The width of the second front side part 310 may refer to the width or diameter of the second front side part 310 along the second direction D2. The width W310 of the second front side part 310 along the second direction D2 may be the same as the width W210 of the first front side part 210.

According to some example embodiments, the second front side part 310 may include a second connection part 311 and a second extension part 312. The second connection part 311 and the second extension part 312 may be placed in the first direction D1.

According to some example embodiments, the second connection part 311 may be inserted into the second back side part 320. The second connection part 311 may be surrounded by the second back side part 320. The second connection part 311 may be overlapped with the second back side part 320 in the second direction D2. The second connection part 311 may be connected to the second extension part 312 and first direction D1.

According to some example embodiments, the second extension part 312 may extend in the first direction D1 across the substrate 100 and the device layer 110. The second extension part 312 may be connected to the wiring layer 112. The second extension part 312 may electrically connect the wiring layer 112 and the second connection part 311. The second extension part 312 may penetrate at least a portion of the substrate 100 and at least a portion of the device layer 110. The second extension part 312 may not overlap the second back side part 320 in the second direction D2. The second extension part 312 may be connected to the second connection part 311 in the first direction D1.

According to some example embodiments, the second back side part 320 may be positioned closer to the back side 100BS of the substrate 100 than the second front side part 310. The second back side part 320 may be placed within the substrate 100. The second back side part 320 may be connected to the second front side part 310 in the first direction D1. The second back side part 320 may surround at least a portion of the second front side part 310. The second back side part 320 may surround the second connection part 311 of the second front side part 310. According to some example embodiments, the second back side part 320 may have a constant width in the second direction D2.

According to some example embodiments, the width of the second back side part 320 may be greater than the width of the second front side part 310. For example, the maximum width W320 of the second back side part 320 may be greater than the maximum width W310 of the second front side part 310. The width of the second back side part 320 along the second direction D2 may be constant.

According to some example embodiments, the first front side part 210 may include a first end part 210E positioned within the first back side part 220. For example, the first end part 210E may be one side of the first connection part 211 facing the back side 100BS of the substrate 100. The first end part 210E may be covered by the first back side part 220. The second front side part 310 may include a second end part 310E positioned within the second back side part 320. For example, the second end part 310E may be one side of the second connection part 311 facing the back side 100BS of the substrate 100. The second end part 310E may be covered by the second back side part 320. The distance between the back side 100BS of the substrate 100 and the first end part 210E along the first direction D1 and the distance between the back side 100BS of the substrate 100 and the second end part 310E along the first direction D1 may be the same.

According to some example embodiments, the first back side part 220 may include a first surface S1 facing the device layer 110. The second back side part 320 may include a second surface S2 facing the device layer 110. Based on the back side 100BS of the substrate 100, the depth of the first surface S1 and the depth of the second surface S2 along the first direction D1 may be the same. The first surface S1 of the first back side part 220 and the second surface S2 of the second back side part 320 may be placed on the same plane.

According to some example embodiments, the length of the first connection part 211 and the length of the second connection part 311 along the first direction D1 may be the same. The distance between the first end part 210E of the first front side part 210 and the first surface S1 of the first back side part 220 along the first direction D1 may be equal to the distance between the second end part 310E of the second front side part 310 and the second surface S2 of the second back side part 320 along the first direction D1.

According to some example embodiments, the first front side part 210 and the second front side part 310 may be spaced apart from the plurality of semiconductor devices 111 within the device layer 110. The first front side part 210 and the second front side part 310 may partially overlap with the plurality of semiconductor devices 111 within the device layer 110 in the second direction D2. To minimize electrical interference with the plurality of semiconductor devices 111, the first front side part 210 and the second front side part 310 may have restrictions on the width or diameter along the second direction D2. Therefore, in order to reduce the electrical resistance of the first through via 200 and the second through via 300, there may be restrictions on increasing the width of the first front side part 210 and the second front side part 310 along the second direction D2.

According to some example embodiments, the first back side part 220 and the second back side part 320 may not be placed within the device layer 110, and may not overlap with the plurality of semiconductor devices 111 in the second direction D2. Therefore, since the first back side part 220 and the second back side part 320 are less likely to cause electrical interference with the plurality of semiconductor devices 111 than the first front side part 210 and the second front side part 310, it may be easy to increase the width or diameter. Therefore, each of the widths W220 of the first back side part 220 and the width W320 of the second back side part 320 may be larger than the width W210 of the first front side part 210 and the width W310 of the second front side part 310.

According to some example embodiments, the width of the first through via 200 and the width of the second through via 300 may be different. More specifically, the maximum width of the first through via 200 and the maximum width of the second through via 300 may be different. The maximum width of the first through via 200 may be greater than the maximum width of the second through via 300. The width W220 of the first back side part 220 of the first through via 200 may be greater than the width W320 of the second back side part 320 of the second through via 300. Since the width W320 of the second back side part 320 is larger than the width W220 of the first back side part 220, the electrical resistance generated in the second back side part 320 may be less than the electrical resistance generated in the first back side part 220.

According to some example embodiments, the first through via 200 may receive a power signal. The power signal may be transmitted through the first through via 200. The second through via 300 may receive an input/output (I/O) signal. The I/O signal may be transmitted through the second through via 300. The power signal with a higher level than the I/O signal may be transmitted through the first through via 200, which includes the first back side part 220, which has a relatively small electrical resistance due to its wider width than the second back side part 320.

According to some example embodiments, a first via insulation film 250 may surround the first through via 200. The first via insulation film 250 may be placed between the first through via 200 and the substrate 100 and the device layer 110. The first via insulation film 250 may insulate the first through via 200 from the substrate 100 and the device layer 110.

According to some example embodiments, the first via insulation film 250 may include a first front side insulation film 251 and a first back side insulation film 252. The first front side insulation film 251 and the first back side insulation film 252 may be connected. FIG. 1 and FIG. 2 illustrate that the first front side insulation film 251 and the first back side insulation film 252 are separate films. However, the first front side insulation film 251 and the first back side insulation film 252 may be formed as an integral film that is not distinct from each other.

According to some example embodiments, the first front side insulation film 251 may surround the first front side part 210. The first front side insulation film 251 may surround a portion of the side of the first front side part 210. The first front side insulation film 251 may surround at least a portion of the first front side part 210 that does not overlap the first back side part 220.

According to some example embodiments, the first back side insulation film 252 may surround the first back side part 220. The first back side insulation film 252 may surround the first surface S1 and the side surface of the first back side part 220.

According to some example embodiments, the thickness of the first front side insulation film 251 may be less than the thickness of the first back side insulation film 252. The permittivity of the first front side insulation film 251 may be greater than the permittivity of the first back side insulation film 252. Therefore, the electrical insulation properties between the plurality of semiconductor devices 111 within the device layer 110 and the first front side part 210 may be improved by the first front side insulation film 251.

According to some example embodiments, a second via insulation film 350 may include a second front side insulation film 351 and a second back side insulation film 352. The second front side insulation film 351 and the second back side insulation film 352 may be connected. FIG. 1 and FIG. 2 illustrate that the second front side insulation film 351 and the second back side insulation film 352 are separate films. However, the second front side insulation film 351 and the second back side insulation film 352 may be formed as an integral film that is not distinct from each other.

According to some example embodiments, the second front side insulation film 351 may surround the second front side part 310. The second front side insulation film 351 may surround a portion of the side of the second front side part 310. The second front side insulation film 351 may surround at least a portion of the second front side part 310 that does not overlap the second back side part 320.

According to some example embodiments, the second back side insulation film 352 may surround the second back side part 320. The second back side insulation film 352 may surround the second surface S2 and the side surface of the second back side part 320.

According to some example embodiments, the thickness of the second front side insulation film 351 may be less than the thickness of the second back side insulation film 352. The permittivity of the second front side insulation film 351 may be greater than the permittivity of the second back side insulation film 352. Therefore, the electrical insulation properties between the plurality of semiconductor devices 111 within the device layer 110 and the second front side part 310 may be improved by the second front side insulation film 351.

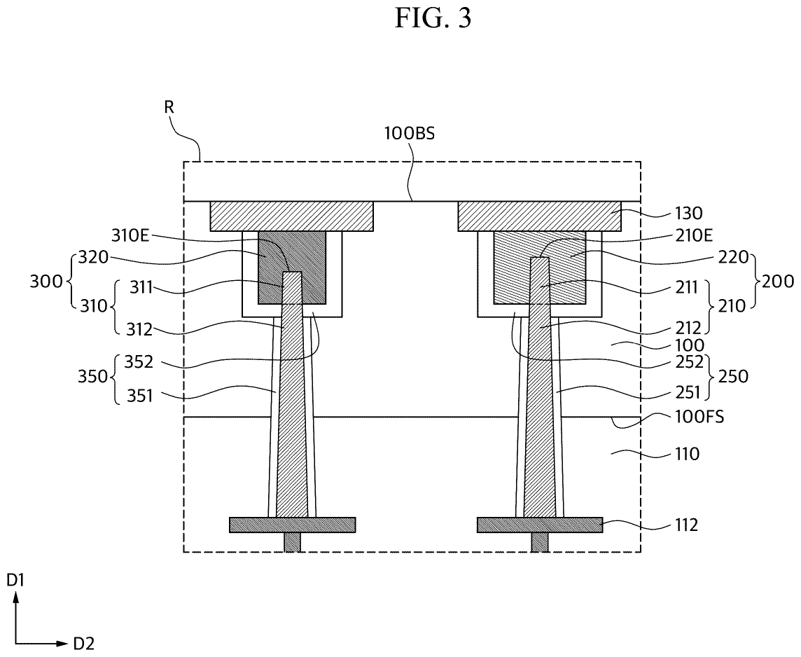

FIG. 3 is a drawing illustrating an enlarged view of the portion R of FIG. 1 to explain a semiconductor chip according to an example embodiment. In order to explain the semiconductor chip according to some other example embodiments, the differences from those described with reference to FIG. 1 and FIG. 2 are mainly described.

Referring to FIG. 3, the distance between the back side 100BS of the substrate 100 and the first end part 210E along the first direction D1 and the distance between the back side 100BS of the substrate 100 and the second end part 310E along the first direction D1 may be different. For example, the distance between the back side 100BS of the substrate 100 and the first end part 210E along the first direction D1 may be smaller than the distance between the back side 100BS of the substrate 100 and the second end part 310E along the first direction D1. The first end part 210E may be placed closer to the back side connecting pad 130 than the second end part 310E.

According to some example embodiments, the length of the first connection part 211 and the length of the second connection part 311 along the first direction D1 may be different. The length of the first connection part 211 along the first direction D1 may be greater than the length of the second connection part 311. The length of overlap between the first back side part 220 and the first front side part 210 in the second direction D2 may be different from the length of overlap between the second back side part 320 and the second front side part 310. The overlapping length of the first back side part 220 and the first front side part 210 in the second direction D2 may be greater than the overlapping length of the second back side part 320 and the second front side part 310. The first front side part 210 may be inserted relatively further into the first back side part 220 than the second front side part 310.

According to some example embodiments, the first front side part 210 and the second front side part 310 may be formed on the front side 100FS of the substrate 100. Therefore, the length of the first front side part 210 and the length of the second front side part 310 formed from the front side 100FS of the substrate 100 toward the back side 100BS of the substrate 100 may be different from each other. Further, the first back side part 220 and the second back side part 320 may be formed on the back side 100BS of the substrate 100. Therefore, even though the distances from the back side 100BS of the substrate 100 to the first front side part 210 and the distance from the back side 100BS of the substrate 100 to the second front side part 310 are different from each other, since the first back side part 220 and the second back side part 320 are formed to be connected to the first front side part 210 and the second front side part 310, there is no need to perform a planarization process such as chemical mechanical polishing (CMP) on the back side 100BS of the substrate 100 in order for the length of the first front side part 210 and the length of the second front side part 310 to be the same. Thus, the process may be simplified.

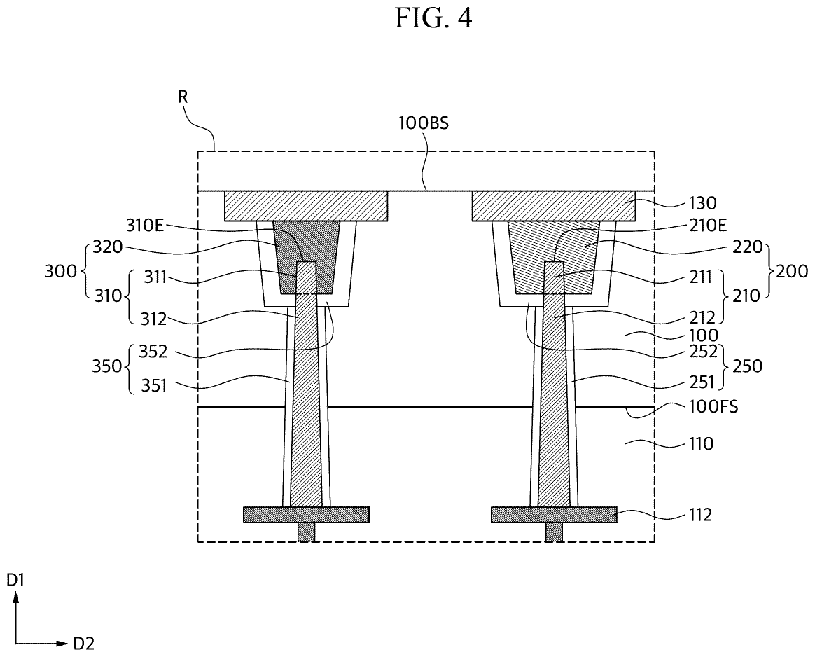

FIG. 4 is a drawing illustrating an enlarged portion of portion R of FIG. 1 to explain a semiconductor chip according to an example embodiment. In order to explain a semiconductor chip according to some example embodiments, the differences from those described with reference to FIG. 1 and FIG. 2 are mainly described.

Referring to FIG. 4, the width of the first back side part 220 may be reduced as the first back side part 220 approaches the first front side part 210. For example, the width of one side of the first back side part 220 through which the first front side part 210 penetrates may be smaller than the width of one side of the first back side part 220 that comes into contact with the back side connecting pad 130.

According to some example embodiments, the width of the second back side part 320 may be reduced as the second back side part 320 approaches the second front side part 310. For example, the width of one side of the second back side part 320 through which the second front side part 310 penetrates may be smaller than the width of one side of the second back side part 320 that comes into contact with the back side connecting pad 130.

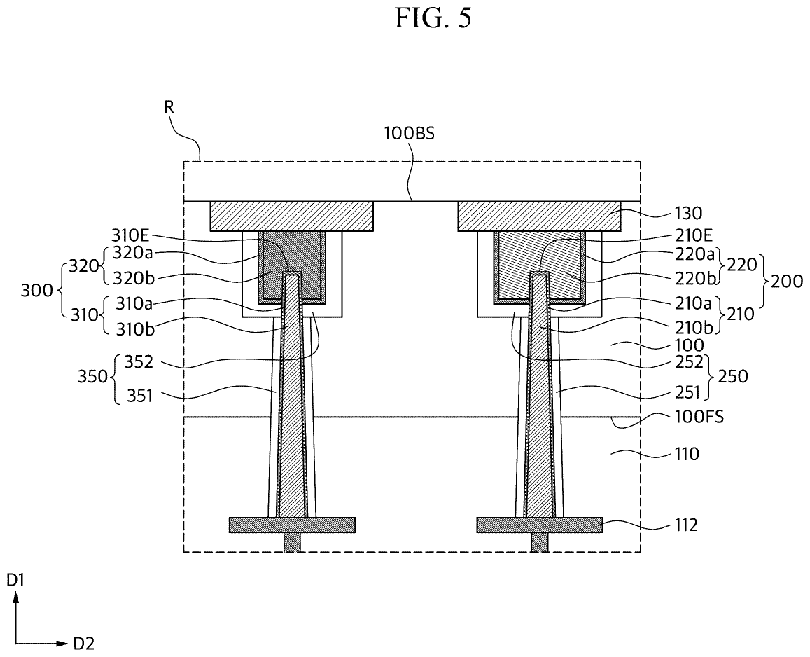

FIG. 5 is a drawing illustrating an enlarged view of the portion R of FIG. 1 to explain a semiconductor chip according to an example embodiment. In order to explain a semiconductor chip according to some example embodiments, the differences from those described with reference to FIG. 1 and FIG. 2 are mainly described.

Referring to FIG. 5, the first through via 200 and the second through via 300 may have a multi-layered film structure. Each of the first front side part 210, the first back side part 220, the second front side part 310 and the second back side part 320 may include a multi-layered film. The first through via 200 and the second through via 300 may include a barrier film formed on a columnar surface and a filling film filling the inside of the barrier film.

According to some example embodiments, the first front side part 210 may include a first front side barrier film 210a and a first front side filling film 210b. The first back side part 220 may include a first back side barrier film 220a and a first back side filling film 220b. Each of the first front side barrier film 210a and the first back side barrier film 220a may surround the first front side filling film 210b and the first back side filling film 220b. Each of the first front side barrier film 210a and the first back side barrier film 220a may include at least one of Ti, TiN, Ta, TaN, Ru, Co, Mn, WN, Ni and NiB, but the first front side barrier film 210a and the first back side barrier film 220a are not limited thereto. Each of the first front side filling film 210b and the first back side filling film 220b may include at least one of Cu alloys such as Cu, CuSn, CuMg, CuNi, CuZn, CuPd, CuAu, CuRe, CuW, W, W alloy, Ni, Ru and Co, but the first front side filling film 210b and the first back side filling film 220b are not limited thereto.

According to some example embodiments, the second front side part 310 may include a second front side barrier film 310a and a second front side filling film 310b. The second back side part 320 may include a second back side barrier film 320a and a second back side filling film 320b. Each of the second front side barrier film 310a and the second back side barrier film 320a may surround the second front side filling film 310b and the second back side filling film 320b. Each of the second front side barrier film 310a and the second back side barrier film 320a may include at least one of Ti, TiN, Ta, TaN, Ru, Co, Mn, WN, Ni and NiB, but the second front side barrier film 310a and the second back side barrier film 320a are not limited thereto. Each of the second front side filling film 310b and the second back side filling film 320b may include at least one of Cu alloys such as Cu, CuSn, CuMg, CuNi, CuZn, CuPd, CuAu, CuRe, and CuW, W, W alloy, Ni, Ru and Co, but the second front side filling film 310b and the second back side filling film 320b are not limited thereto.

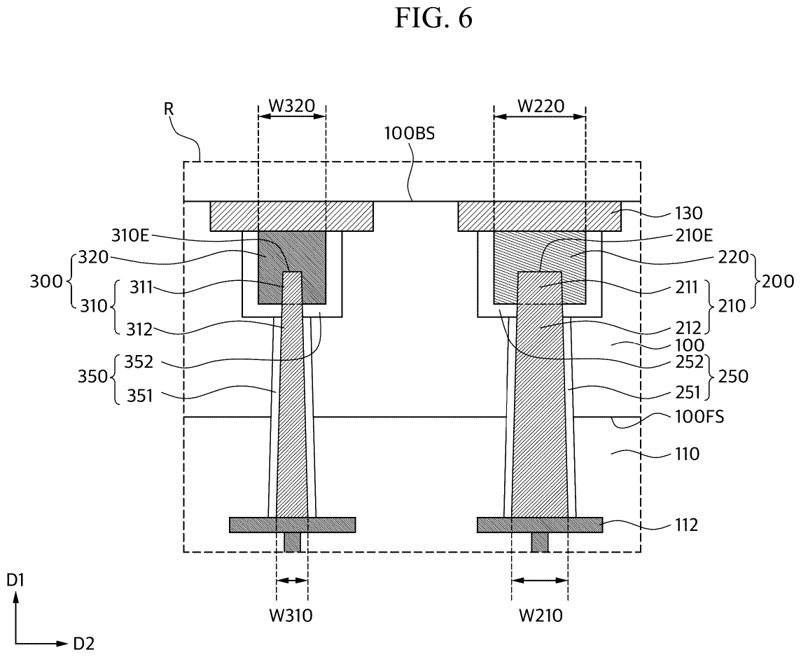

FIG. 6 is a drawing illustrating an enlarged view of the portion R of FIG. 1 to explain a semiconductor chip according to an example embodiment. In order to explain a semiconductor chip according to some example embodiments, the differences from those described with reference to FIG. 1 and FIG. 2 are mainly described.

Referring to FIG. 6, the width W210 of the first front side part 210 and the width W310 of the second front side part 310 along the second direction D2 may be different from each other. For example, the width W210 of the first front side part 210 may be greater than the width W310 of the second front side part 310. The width W210 of the first front side part 210 may refer to the maximum width of the first front side part 210. The width W310 of the second front side part 310 may refer to the maximum width of the second front side part 310. A power signal with a higher level than the I/O signal may be transmitted through the first through via 200, which includes the first front side part 210, which has a relatively small electrical resistance due to its wider width compared to the second front side part 310.

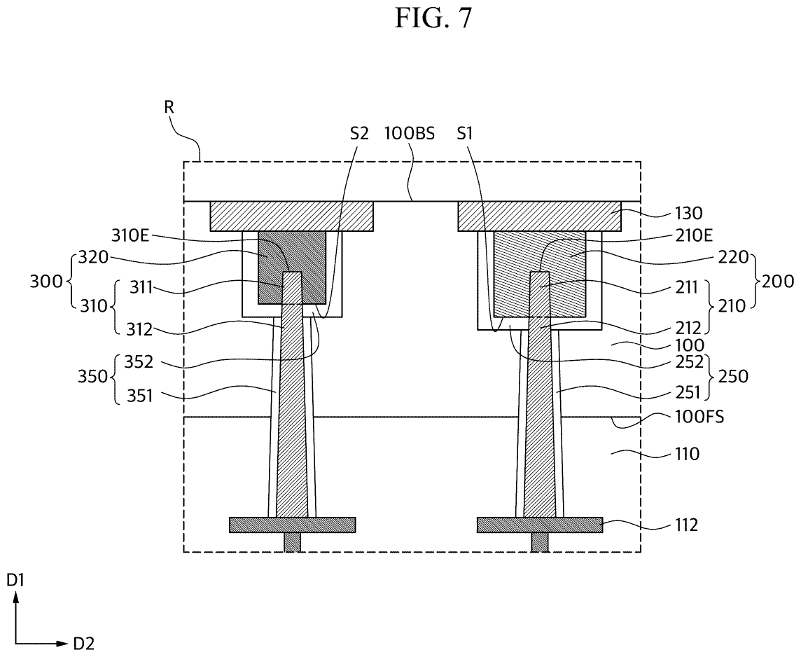

FIG. 7 is a drawing illustrating an enlarged view of the portion R of FIG. 1 to explain a semiconductor chip according to an example embodiment. In order to explain a semiconductor chip according to some example embodiments, the differences from those described with reference to FIG. 1 and FIG. 2 are mainly described.

Referring to FIG. 7, based on the back side 100BS of the substrate 100, the depth of the first surface S1 and the depth of the second surface S2 along the first direction D1 may be different from each other. For example, based on the back side 100BS of the substrate 100, the depth of the first surface S1 along the first direction D1 may be greater than the depth of the second surface S2. The first surface S1 of the first back side part 220 may be positioned closer to the front side 100FS of the substrate 100 than the second surface S2 of the second back side part 320.

According to some example embodiments, the length of the first connection part 211 and the length of the second connection part 311 along the first direction D1 may be different. The length of the first connection part 211 along the first direction D1 may be greater than the length of the second connection part 311. The distance between the first end part 210E of the first front side part 210 and the first surface S1 of the first back side part 220 along the first direction D1 may be greater than the distance between the second end part 310E of the second front side part 310 and the second surface S2 of the second back side part 320 along the first direction D1.

According to some example embodiments, the contact area between the first front side part 210 and the first back side part 220 may be larger than the contact area between the second front side part 310 and the second back side part 320. Therefore, the electrical resistance of the first through via 200 including the first front side part 210 and the first back side part 220 may be alleviated, and the power signal may be transmitted stably through the first through via 200.

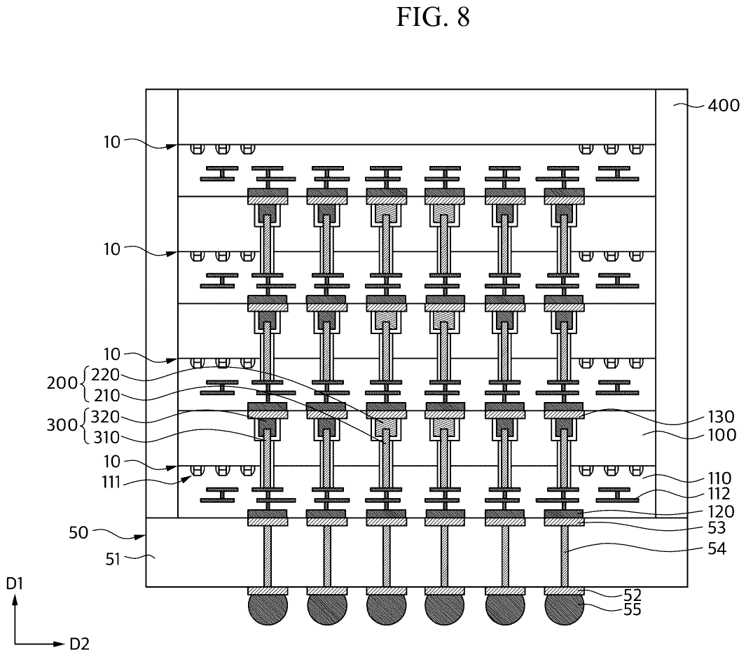

FIG. 8 is a schematic drawing illustrating a semiconductor package according to an example embodiment. For convenience of explanation, the differences from those described with reference to FIG. 1 and FIG. 2 are mainly described.

Referring to FIG. 8, the semiconductor package according to the example embodiment may include a package die 50, a plurality of semiconductor chips 10 and a molding film 400.

According to some example embodiments, the package die 50 may be placed on the lower portion of a plurality of semiconductor chips 10. The package die 50 may be electrically connected to a plurality of semiconductor chips 10. The plurality of semiconductor chips 10 may exchange electrical signals with an external device through the package die 50.

According to some example embodiments, the package die 50 may be a wiring structure for a package. For example, the package die 50 may be a printed circuit board (PCB), a ceramic substrate, or an interposer. Alternatively, the package die 50 may be a wiring structure for a wafer level package (WLP) manufactured at the wafer level. The package die 50 may be a semiconductor chip containing a semiconductor device. The package die 50 may function as a support substrate for a semiconductor package. The package die 50 may be a buffer chip connected to a plurality of semiconductor chips 10.

According to some example embodiments, the package die 50 may be a glass substrate, a ceramic substrate or a plastic substrate, but the package die 50 is not limited thereto. For example, the package die 50 may include a resin impregnated in a core material such as glass fiber (glass cloth, glass fabric) with an inorganic filler, Prepreg, Ajinomoto Build-up Film (ABF), FR-4 and Bismaleimide Triazine (BT).

According to some example embodiments, the package die 50 may include, for example, bulk silicon or silicon-on-insulator (SOI). In another example embodiment, the package die 50 may be a silicon substrate. In another example embodiment, the package die 50 may include silicon germanium, silicon germanium on insulator (SGOI), indium antimonide, lead telluride, indium arsenide, indium phosphide, gallium arsenide or gallium antimonide. However, the package die 50 is not limited thereto.

According to some example embodiments, the package die 50 may include a conductive region, for example, a doped well or a doped structure. The package die 50 may have various device isolation structures, such as shallow trench isolation (STI) structures.

According to some example embodiments, the package die 50 may include a body part 51, a lower portion bonding pad 52, an upper portion bonding pad 53 and a connecting via 54.

According to some example embodiments, when the package die 50 is a printed circuit substrate, the body part 51 may be made of at least one material selected from phenol resin, epoxy resin, and polyimide. The package die 50 may include at least one material selected from tetrafunctional epoxy, polyphenylene ether, epoxy/polyphenylene oxide, bismaleimide triazine (BT), thermount, cyanate ester and liquid crystal polymer.

According to some example embodiments, the body part 51 may include a photoimageable dielectric. For example, the body part 51 may include photosensitive polymer. The photosensitive polymer may be formed of at least one of, for example, a photosensitive polyimide, a polybenzoxazole, a phenol-based polymer, and a benzocyclobutene-based polymer. In another example embodiment, the body part 51 may be formed of a silicon oxide film, a silicon nitride film or a silicon oxynitride film.

Even though not illustrated, the surface of the body part 51 may be covered with an upper insulation film and a lower insulation film. The upper insulation film and lower insulation film may protect the substrate wiring structure and other structures within the body part 51 from external impact or moisture. The upper insulation film and the lower insulation film may include solder resist. However, example embodiments are not limited thereto.

According to some example embodiments, the lower portion bonding pad 52 may be placed on the lower portion of the body part 51. The upper portion bonding pad 53 may be positioned within the body part 51. The upper portion bonding pad 53 may be in contact with the front side connecting pad 120 of the semiconductor chip 10. The lower portion bonding pad 52 and the upper portion bonding pad 53 may be connected to the connecting via 54.

Even though not illustrated, a substrate wiring structure may be placed within the body part 51. The substrate wiring structure may include wiring layers and wiring vias connecting each wiring layer. For example, the substrate wiring structure may be a multilayer structure in which two or more wiring layers or two or more wiring vias are alternately stacked. For example, the wiring layer may extend in the second direction D2 or the third direction D3. The wiring vias may connect wiring layers separated in the first direction D1.

According to some example embodiments, the substrate wiring structure may include a conductive material. For example, the substrate wiring structure may include copper (Cu), aluminum (Al), silver (Ag), tin (Sn), gold (Au), nickel (Ni), lead (Pb), titanium (Ti), or alloys thereof. However, the substrate wiring structure is not limited thereto.

According to some example embodiments, an external connection terminal 55 may be formed on the lower portion of the package die 50. The external connection terminal 55 may be placed on the lower portion bonding pad 52. The external connection terminal 55 may contact the lower portion bonding pad 52. The external connection terminal 55 may include a solder ball or solder bump. For example, the external connection terminal 55 may be spherical or elliptical, but is not limited thereto. The number, spacing, arrangement, shape and so on with respect to the external connection terminal 55 are not limited to those illustrated, and it is apparent that the number, spacing, arrangement, shape and so on with respect to the external connection terminal 55 may vary depending on the design. For example, the external connection terminal 55 may include tin (Sn), indium (In), bismuth (Bi), antimony (Sb), copper (Cu), silver (Ag), zinc (Zn), lead (Pb) and combinations thereof, but the external connection terminal 55 is not limited thereto.

According to some example embodiments, the external connection terminal 55 may electrically connect the package die 50 to an external device. Accordingly, the external connection terminal 55 may provide an electrical signal to the package die 50, or may provide an electrical signal provided from the package die 50 to an external device. For example, the external connection terminal 55 may receive signals input to a plurality of semiconductor chips 10. The external connection terminal 55 may receive signals output from a plurality of semiconductor chips 10.

According to some example embodiments, the plurality of semiconductor chips 10 may be stacked on the package die 50. The plurality of semiconductor chips 10 may be stacked on the package die 50 in the first direction D1. Each of the plurality of semiconductor chips 10 may include the first through via 200 and the second through via 300. The first through vias 200 that the plurality of semiconductor chips 10 include may overlap each other in the first direction D1. The second through vias 300 that the plurality of semiconductor chips 10 include may overlap each other in the first direction D1. The plurality of semiconductor chips 10 are substantially identical to the semiconductor chips 10 described with reference to FIG. 1 to FIG. 7, and thus a description of the plurality of semiconductor chips 10 is omitted below. FIG. 8 illustrates that four semiconductor chips are stacked, but example embodiments are not limited thereto. The number of semiconductor chips 10 that are stacked may vary according to example embodiments.

According to some example embodiments, the molding film 400 may be formed on the package die 50. The molding film 400 may cover the plurality of semiconductor chips 10. The molding film 400 may include a polymer, such as resin. For example, the molding film 400 may include an epoxy molding compound (EMC), but the molding film 400 is not limited thereto.

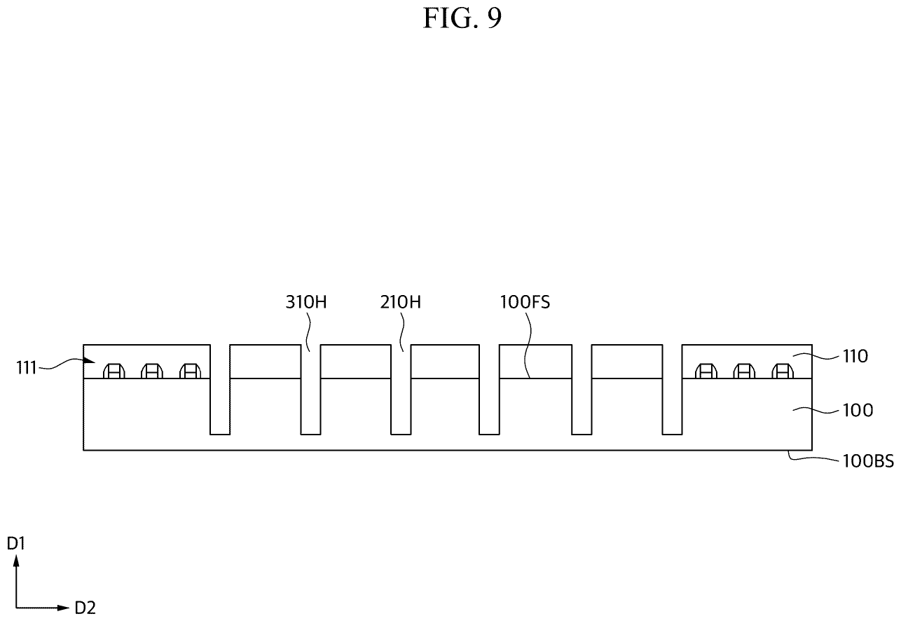

FIG. 9 to FIG. 16 are schematic drawings illustrating intermediate operations for explaining a method of manufacturing a semiconductor chip according to the example embodiment illustrated in FIG. 1.

Referring to FIG. 9, the device layer 110 may be formed on the substrate 100. The plurality of semiconductor devices 111 may be formed on the front side 100FS of the substrate 100. In addition, a hole 210H of the first front side part 210 and a hole 310H of the second front side part 310 may be formed penetrating the substrate 100 and the device layer 110. The hole 210H of the first front side part 210 and the hole 310H of the second front side part 310 may be formed to be spaced apart from the plurality of semiconductor devices 111. The hole 210H of the first front side part 210 and the hole 310H of the second front side part 310 may be formed in an area where the plurality of semiconductor devices 111 are not placed.

According to some example embodiments, the hole 210H of the first front side part 210 and the hole 310H of the second front side part 310 may be formed on the front side 100FS of the substrate 100 toward the back side 100BS of the substrate 100. The hole 210H of the first front side part 210 and the hole 310H of the second front side part 310 may penetrate the front side 100FS of the substrate 100. The hole 210H of the first front side part 210 and the hole 310H of the second front side part 310 may not penetrate the back side 100BS of the substrate 100.

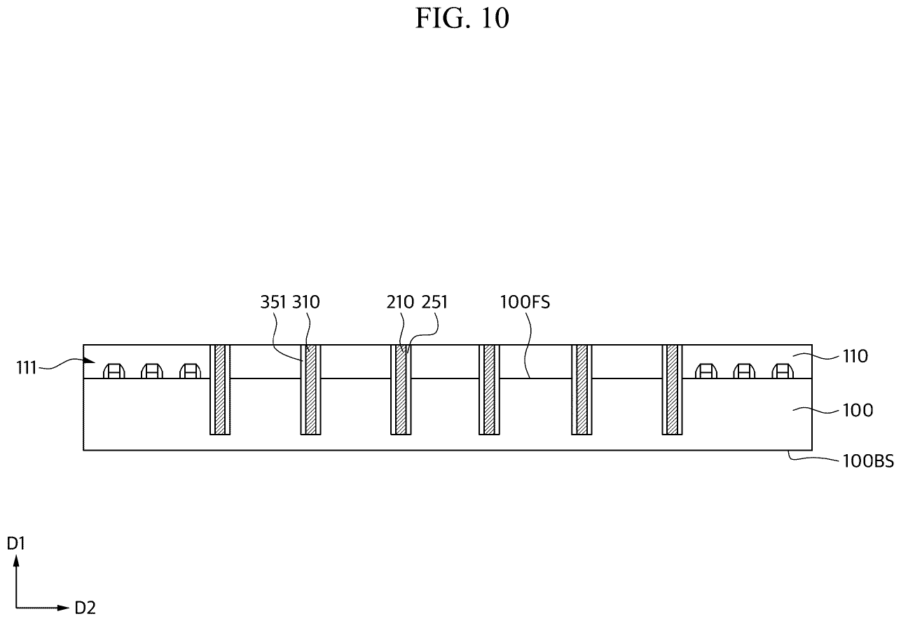

Referring to FIG. 10, the first front side insulation film 251 of the first front side part 210 and the first front side part 210 may be formed within the hole 210H (of FIG. 9) of the first front side part 210. The second front side insulation film 351 and the second front side part 310 may be formed within the hole 310H (of FIG. 9) of the second front side part 310. Each of the first front side insulation film 251 of the first front side part 210 and the second front side insulation film 351 may surround the first front side part 210 and the second front side part 310.

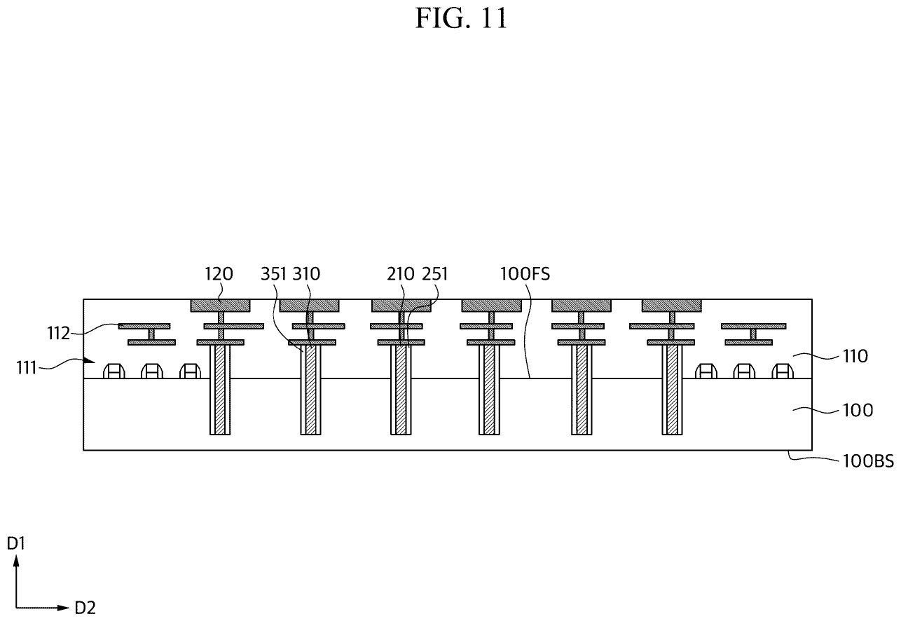

Referring to FIG. 11, the wiring layer 112 and the front side connecting pad 120 may be formed within the device layer 110. The wiring layer 112 may be formed on the front side 100FS of the substrate 100. The wiring layer 112 may be formed after the first front side part 210 and the second front side part 310 are formed. The wiring layer 112 may be connected to the first front side part 210 and the second front side part 310.

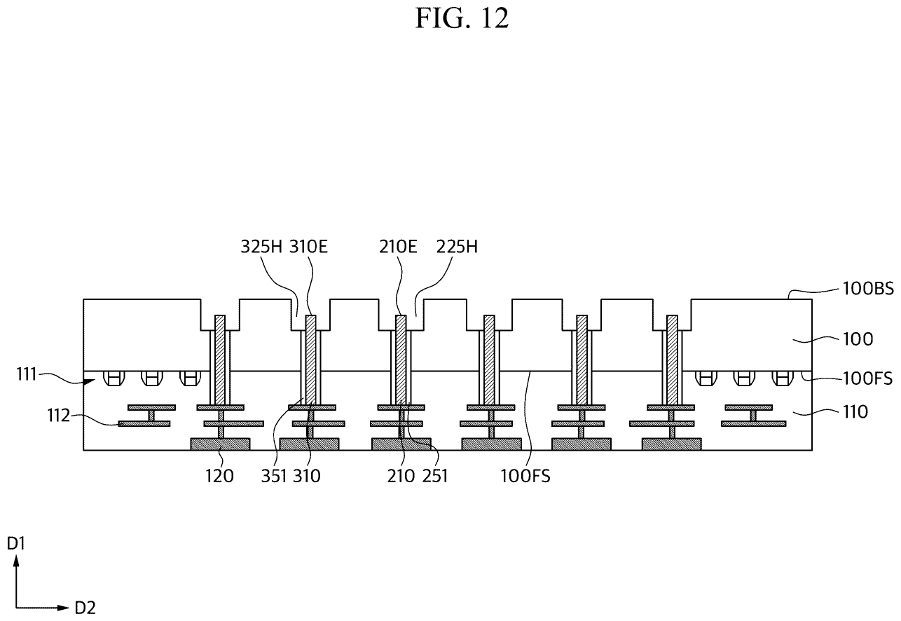

Referring to FIG. 12, a first back side hole 225H and a second back side hole 325H may be formed. The first back side hole 225H and the second back side hole 325H may be formed on the back side 100BS of the substrate 100. The first back side hole 225H and the second back side hole 325H may be formed from the back side 100BS of the substrate 100 toward the front side 100FS of the substrate 100. The first back side hole 225H and the second back side hole 325H may be formed in the substrate 100 on which the plurality of semiconductor devices 111 are not formed. The first end part 210E of the first front side part 210 and the second end part 310E of the second front side part 310 may be exposed through the first back side hole 225H and the second back side hole 325H.

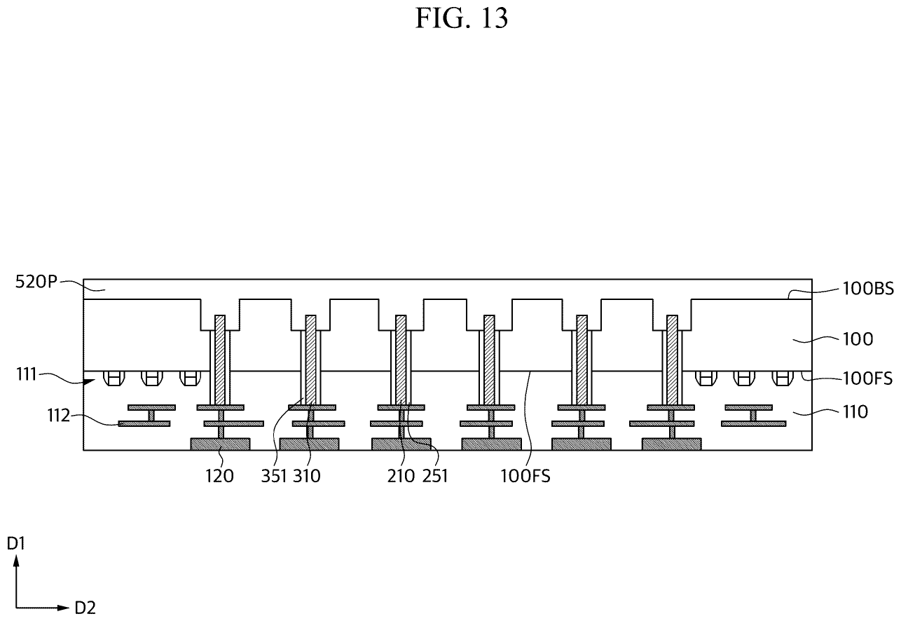

Referring to FIG. 13, a pre-back side insulation film 520P may be formed on the back side 100BS of the substrate 100 to fill the first back side hole 225H (in FIG. 12) and the second back side hole 325H (in FIG. 12). The pre-back side insulation film 520P may cover the first end part 210E (of FIG. 12) of the first front side part 210 and the second end part 310E (of FIG. 12) of the second front side part 310 within the first back side hole 225H (of FIG. 12) and the second back side hole 325H (of FIG. 12).

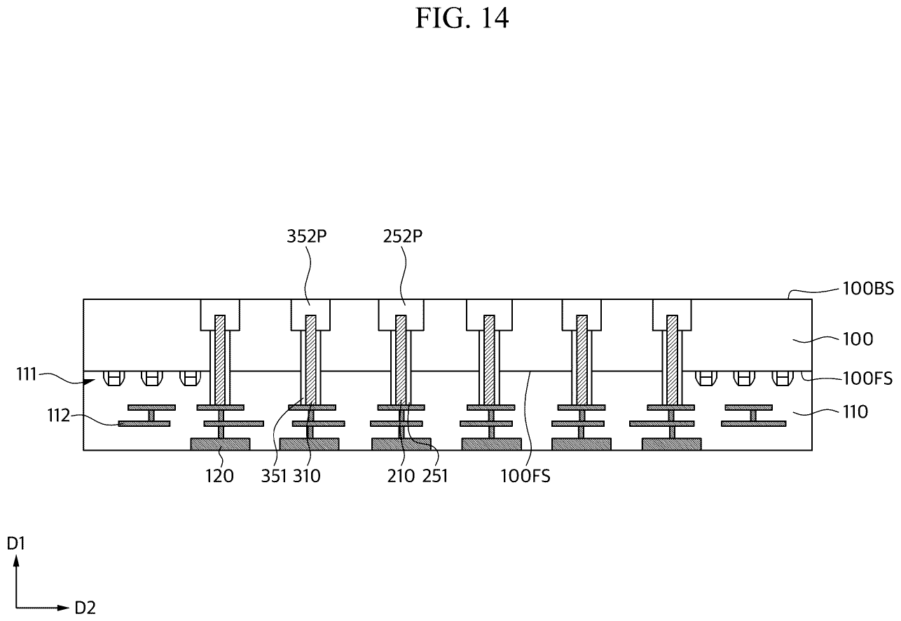

Referring to FIG. 14, a portion of the pre-back side insulation film 520P covering the back side 100BS of the substrate 100 may be removed. The pre-back side insulation film 520P and the back side 100BS of the substrate 100 may be placed on the same plane.

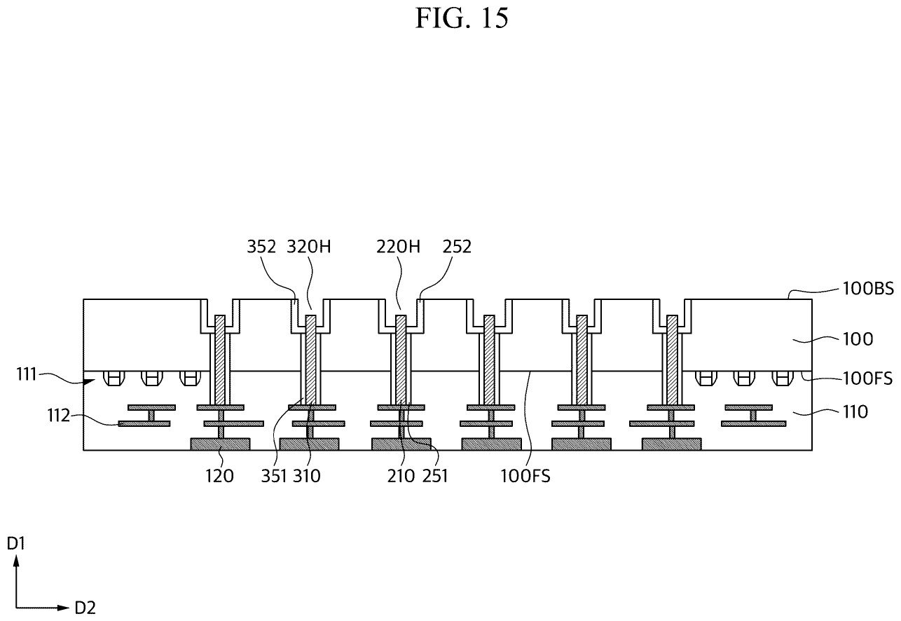

Referring to FIG. 15, a hole 220H of the first back side part 220 and a hole 320H of the second back side part 320 may be formed. The width of the hole 220H of the first back side part 220 and the width of the hole 320H of the second back side part 320 may be different from each other. The width of the hole 220H of the first back side part 220 may be greater than the width of the hole 320H of the second back side part 320. The first end part 210E of the first front side part 210 and the second end part 310E of the second front side part 310 may be exposed again within the hole 220H of the first back side part 220 and the hole 320H of the second back side part 320.

According to some example embodiments, the pre-back side insulation film 520P (in FIG. 14) may be patterned. The pre-back side insulation film 520P (in FIG. 14) may be patterned to form the first back side insulation film 252 and the second back side insulation film 352. The first back side insulation film 252 and the second back side insulation film 352 may surround the hole 220H of the first back side part 220 and the hole 320H of the second back side part 320.

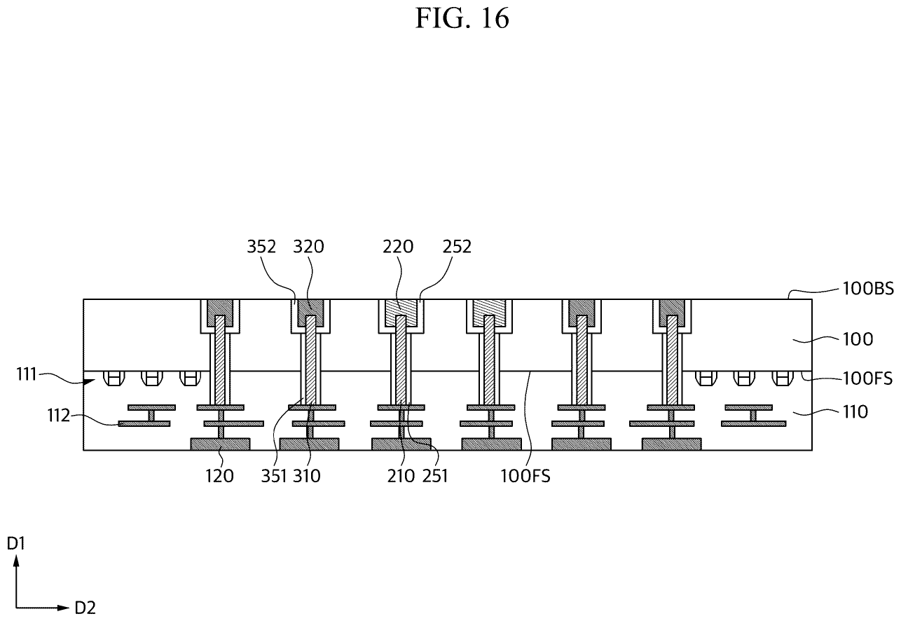

Referring to FIG. 16, the first back side part 220 and the second back side part 320 may be formed on the first back side insulation film 252 and the second back side insulation film 352.

In addition, referring to FIG. 1, the back side connecting pad 130 may be formed on the first back side insulation film 252 and the second back side insulation film 352.

According to example embodiments, it is possible to alleviate the electrical resistance of semiconductor chips and semiconductor packages.

According to example embodiments, it is possible to improve the manufacturing process of semiconductor chips and semiconductor packages.

In the above, various embodiments of the present disclosure are described in detail. However, it will be apparent to those with average knowledge in the technical field that scope of rights of this disclosure is not limited thereto, and various modifications and variations are possible without departing from the technical spirit of the present disclosure as set forth in the claims. Further, the above-described example embodiment may be implemented with some elements deleted, and each example embodiment may be implemented in combination with each other.

What is claimed is:

1. A semiconductor chip comprising:
a device layer comprising a semiconductor device disposed on a front side of a substrate; and
a first through via extending in a first direction intersecting the front side of the substrate and penetrating the substrate and at least a portion of the device layer,
wherein the first through via comprises:
a first front side part penetrating the front side of the substrate and penetrating at least the portion of the device layer; and
a first back side part disposed in the substrate, connected to the first front side part and placed closer to a back side of the substrate than the first front side part,
wherein the first back side part comprises a width that is greater than a width of the first front side part.

2. The semiconductor chip of claim 1, further comprising a first via insulation film surrounding the first through via,
wherein the first via insulation film comprises:
a first front side insulation film surrounding the first front side part; and
a first back side insulation film surrounding the first back side part,
wherein a thickness of the first front side insulation film is less than a thickness of the first back side insulation film.

3. The semiconductor chip of claim 2, wherein permittivity of the first front side insulation film is greater than permittivity of the first back side insulation film.

4. The semiconductor chip of claim 2, wherein the first front side insulation film surrounds at least a portion of the first front side part that does not overlap with the first back side part in a second direction intersecting the first direction.

5. The semiconductor chip of claim 1, wherein the first front side part comprises:
a first connection part that is inserted into the first back side part; and
a first extension part that does not overlap with the first back side part in a second direction intersecting the first direction.

6. The semiconductor chip of claim 1, wherein a plurality of first through vias are disposed in a second direction intersecting the first direction.

7. The semiconductor chip of claim 1, wherein each of the first front side part and the first back side part comprises a multi-layered film.

8. The semiconductor chip of claim 1, wherein the device layer further comprises a wiring layer connected to the first through via.

9. The semiconductor chip of claim 8, further comprising:
a back side connecting pad that is connected to the first through via and placed on the back side of the substrate; and
a front side connecting pad that is connected to the wiring layer and placed on the front side of the substrate.

10. The semiconductor chip of claim 1, wherein the first front side part comprises a width that decreases as the first front side part approaches the first back side part.

11. The semiconductor chip of claim 1, wherein the first back side part comprises a width that decreases as the first back side part approaches the first front side part.

12. A semiconductor chip comprising:
a device layer comprising a semiconductor device disposed on a front side of a substrate;
a first through via extending in a first direction intersecting the front side of the substrate and penetrating the substrate and at least a portion of the device layer; and
a second through via that is spaced apart from the first through via in a second direction intersecting the first direction, and penetrating the substrate and at least an other portion of the device layer,
wherein the first through via comprises:
a first front side part penetrating the front side of the substrate and penetrating at least the portion of the device layer; and
a first back side part that disposed in the substrate, connected to the first front side part and placed closer to a back side of the substrate compared to the first front side part, and
wherein the second through via comprises:
a second front side part penetrating the front side of the substrate and penetrating at least the other portion of the device layer; and
a second back side part that disposed in the substrate, connected to the second front side part, and placed closer to the back side of the substrate compared to the second front side part,
wherein the first side part comprises a width that is greater than a width of the second back side part.

13. The semiconductor chip of claim 12, wherein the width of the first back side part is greater than the width of the first front side part, and
wherein the width of the second back side part is greater than the width of the second front side part.

14. The semiconductor chip of claim 12, wherein the first front side part comprises a first end part disposed in the first back side part,
wherein the second front side part comprises a second end part disposed in the second back side part, and
wherein a distance between the back side of the substrate and the first end part in the first direction is different from a distance between the back side of the substrate and the second end part in the first direction.

15. The semiconductor chip of claim 12, wherein the first front side part comprises:
a first connection part that is inserted into the first back side part; and
a first extension part that does not overlap with the first back side part in the second direction, and
wherein the second front side part comprises:
a second connection part that is inserted into the second back side part; and
a second extension part that does not overlap with the second back side part in the second direction.

16. The semiconductor chip of claim 15, wherein a length of the first connection part in the first direction is different from a length of the second connection part in the first direction.

17. The semiconductor chip of claim 12, wherein,
based on the back side of the substrate,
a depth of a first surface of the first back side part facing the device layer and a depth of a second surface of the second back side part facing the device layer are different from each other.

18. The semiconductor chip of claim 12, wherein the first front side part comprises a width that is equal to or greater than a width of the second front side part.

19. The semiconductor chip of claim 12, wherein,
a power signal is transmitted through the first through via, and
an input/output (I/O) signal is transmitted through the second through via.

20. A semiconductor package comprising:
a package die; and
a plurality of semiconductor chips that are stacked in a first direction intersecting the package die,
wherein each of the plurality of semiconductor chips comprises:
a device layer comprising a semiconductor device placed on a front side of a substrate;
a first through via extending in the first direction and penetrating the substrate and at least a portion of the device layer; and
a second through via that is spaced apart from the first through via in a second direction intersecting the first direction, and penetrating the substrate and at least an other portion of the device layer,
wherein the first through via comprises:
a first front side part penetrating the front side of the substrate and penetrating at least the portion of the device layer; and
a first back side part disposed in the substrate, connected to the first front side part and placed closer to a back side of the substrate compared to the first front side part,
wherein the second through via comprises:
a second front side part penetrating the front side of the substrate and penetrating at least the other portion of the device layer; and
a second back side part disposed in the substrate, connected to the second front side part, and placed closer to the back side of the substrate compared to the second front side part,
wherein a maximum width of the first back side part is greater than a maximum width of the second back side part,
wherein a plurality of the first through vias of the plurality of semiconductor chips overlap each other in the first direction, and
wherein a plurality of the second through vias of the plurality of semiconductor chips overlap each other in the first direction.
